(19) United States
(12) Patent Application Publication
(10) Pub. No.: US 2007/0102735 A1
(43) Pub. Date: May 10, 2007

(54) SEMICONDUCTOR DEVICE AND METHOD FOR MANUFACTURING THE SEMICONDUCTOR DEVICE

(75) Inventors: Kei KANEMOTO, Suwa-shi, Nagano-ken (JP); Hideaki OKA, Suwa-shi, Nagano-ken (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/537,865

(22) Filed: Oct. 2, 2006

(30) Foreign Application Priority Data
Nov. 10, 2005 (JP) 2005-325831
Nov. 10, 2005 (JP) 2005-325832
Nov. 10, 2005 (JP) 2005-325729
Jul. 26, 2006 (JP) 2006-202677

(51) Int. Cl. H01L 29/78; H01L 21/336

(52) U.S. Cl. 257/288; 257/347; 257/506; 438/294; 438/197; 438/151

(57) ABSTRACT

A semiconductor device includes: a semiconductor substrate; a well formed on the semiconductor substrate; a semiconductor layer formed by epitaxial growth avoiding the well; a buried insulating layer embedded between the semiconductor substrate and the semiconductor layer; a first gate electrode formed on the semiconductor layer, the first gate electrode having a first side and a second side; a first source layer and a first drain layer formed on the semiconductor layer, the first source layer being arranged on the first side of the first gate electrode and the first drain layer being arranged on the second side of the first gate electrode; a second gate electrode formed on the well, the second gate electrode having a third side and a fourth side; and a second source layer and a second drain layer formed on the well, the second source layer being arranged on the third side of the second gate electrode and the second drain layer being arranged on the fourth side of the second gate electrode.

### BACKGROUND

1. Technical Field

The present invention relates to a semiconductor device and a method for manufacturing the semiconductor device, and is particularly suitable for applying to a method mounting a silicon on insulator (SO) structure and a bulk structure on the same substrate.

2. Related Art

A field-effect transistor formed on an SOI substrate has been drawing attention recently because of its usability in terms of easy-element isolation, latch-up free, and small source/drain junction capacitance. Especially, since a fully depleted SOI transistor enabling low power consumption and high-speed operation is easy to drive at low voltage, researches to drive an SOI transistor in a fully depleted mode are actively carried out. As the SOI substrate here, a separation by implanted oxygen (SIMOX) substrate, a bonded substrate or the like is used, for example.

A method capable of manufacturing an SOI transistor economically by forming an SOI layer on a bulk substrate is disclosed in Separation by Bonding Si islands (SBSI) for LSI Applications (T,Sakai et al.), Second International SiGe Technology and Device Meeting, Meeting Abstract, pp. 230-231, May (2004). In this method, Si/SiGe layer is deposited on a Si substrate, and only the SiGe layer is selectively removed by using difference of the selectivity ratio between Si and SiGe so as to form a cavity between the Si substrate and the Si layer. Then, a SiO₂ layer is embedded between the Si substrate and the Si layer by thermally oxidizing the Si exposed in the cavity so as to form a BOX layer between the Si substrate and the Si layer.

On the other hand, a field-effect transistor requiring a high breakdown voltage due to its large current drive power is desired to be formed on a bulk substrate isolated by a local oxidation of silicon (LOCOS) as it is hard to form on an SO substrate which has a limitation of a silicon layer thickness. When a bulk structure isolated by a LOCOS and an SOI structure are mounted in combination, a shallow trench isolation (STI) structure is formed outside of an active region defined by the LOCOS structure, and a gate electrode is arranged to cross the LOCOS structure via the STI structure.

However, in the case where the bulk structure and the SOI structure are mounted on the same substrate, a well region is formed on a semiconductor substrate, and the bulk structure and the SOI structure are formed on the well region. Therefore, when a Si/SiGe layer is formed on a Si substrate in order to form the SOI structure by SBSI method, the Si/SiGe layer is deposited on the well region that is doped at high concentration, and this causes a crystal defect easily on the Si/SiGe layer.

Further, in the case where a bulk region and an SOI region are mounted on the same substrate, a well region is formed on a semiconductor substrate, and the bulk region and the SOI region are arranged on the well region. Therefore, when a P-channel field-effect transistor and an N-channel field-effect transistor are formed on the bulk region, the P-channel field-effect transistor and the N-channel field-effect transistor to be formed on the SOI region are arranged on an N well and a P well. When the N-channel field-effect transistor is formed on the bulk region, the P-channel field-effect transistor to be formed on the SOI region is arranged on the P well. As a result, when a bias voltage is applied to the well, the field-effect transistor formed on the SOI region receives back bias application unintentionally, adversely affecting operation of a large-scale integration (LSI). For example, if an N-channel field-effect transistor to be formed on the SOI region is arranged on the N well, a positive back bias is applied to the N-channel field-effect transistor. Consequently, a threshold of the N-channel field-effect transistor decreases, and this causes problems such as being a depletion type or occurrence of a leakage current between a source and a drain because a back channel is formed.

Further, in the method to arrange a gate electrode to cross a LOCOS structure via the STI structure, there occurs a problem such as a leak current from the gate electrode to the semiconductor substrate or deterioration of reliability of a gate insulating film because of a risk in which the surface of the semiconductor substrate is exposed at the border between the LOCOS structure and the STI structure.

### SUMMARY

An advantage of the invention is to provide a semiconductor device and a method for manufacturing the semiconductor device capable of having an SOI structure and a bulk structure mounted on the same substrate.

According to a first aspect of the invention, a semiconductor device includes: a semiconductor substrate; a well formed on the semiconductor substrate; a semiconductor layer formed by epitaxial growth avoiding the well; a buried insulating layer embedded between the semiconductor substrate and the semiconductor layer; a first gate electrode formed on the semiconductor layer, the first gate electrode having a first side and a second side; a first source layer and a first drain layer formed on the semiconductor layer, the first source layer being arranged on the first side of the first gate electrode and the first drain layer being arranged on the second side of the first gate electrode; a second gate electrode formed on the well, the second gate electrode having a third side and a fourth side; and a second source layer and a second drain layer formed on the well, the second source layer being arranged on the third side of the second gate electrode and the second drain layer being arranged on the fourth side of the second gate electrode.

Accordingly, it becomes possible to form an SOI structure in a part of the region of the semiconductor substrate without using an SOI substrate. An SOI structure and a bulk structure can thus be formed on the same semiconductor substrate. At the same time, the semiconductor layer is prevented from forming on the well that is heavily doped and crystal defects of the semiconductor layer can be reduced. This enables both an SOI transistor and a high-breakdown-voltage transistor to be mounted on the same semiconductor substrate without using an SOI substrate while manufacturing cost is prevented from increasing. Accordingly, system on chip (SOC) is realized and reliability of the SOI transistor can be improved.

Further, according to a second aspect of the invention, a semiconductor device includes: a semiconductor substrate; a P well formed on the semiconductor substrate; an N well formed on the semiconductor substrate; a semiconductor layer formed by epitaxial growth avoiding the P well and the N well; a buried insulating layer embedded between the semiconductor substrate and the semiconductor layer; a first gate electrode formed on the semiconductor layer, the first gate electrode having a first side and a second side; a source layer and a drain layer formed on the semiconductor layer, the source layer being arranged on the first side of the first gate electrode and the drain layer being arranged on the second side of the first gate electrode; a second gate electrode formed on the P well, the second gate electrode having a third side and a fourth side; an N-type source layer and an N-type drain layer formed on the P well, the N-type source layer being arranged on the third side of the second gate electrode and the N-type drain layer being arranged on the fourth side of the second gate electrode; a third gate electrode formed on the N well, the third gate electrode having a fifth side and a sixth side; and a P-type source layer and a P-type drain layer formed on the N well, the P-type source layer being arranged on the fifth side of the third gate electrode and the P-type drain layer being arranged on the sixth side of the third gate electrode.

Thereby, it becomes possible to form an SOI structure and a bulk structure on the same semiconductor substrate without using an SOI substrate while a CMOS circuit is configured and a crystal defect of the semiconductor layer is reduced. The invention thus can prevent manufacturing cost from increasing, and elements having various functions with excellent characteristics can be formed on the same chip.

Further, according to a third aspect of the invention, a method for manufacturing a semiconductor device includes: forming a well on a semiconductor substrate; forming a first semiconductor layer on the semiconductor substrate avoiding the well; forming a second semiconductor layer having a smaller etching rate than an etching rate of the first semiconductor layer on the first semiconductor layer; forming a support member supporting the second semiconductor layer on the semiconductor substrate; forming an exposing part to expose at least a part of the first semiconductor layer from the second semiconductor layer; selectively etching the first semiconductor layer through the exposing part to form a cavity under the second semiconductor layer by removing the first semiconductor layer; forming a buried insulating layer embedded in the cavity through the exposing part; forming a first gate electrode on the second semiconductor layer through a first gate insulating film, the first gate electrode having a first side and a second side; forming a first, source layer and a first drain layer on the second semiconductor layer, the first source layer being arranged on the first side of the first gate electrode and the first drain layer being arranged on the second side of the first gate electrode; forming a second gate electrode on the well through a second gate insulating film, the second gate electrode having a third side and a fourth side and forming a second source layer and a second drain layer on the well, the second source layer being arranged on the third side of the second gate electrode and a second drain layer being arranged on the fourth side of the second gate electrode.

Thereby, it becomes possible to mount an SOI element and a bulk element can be formed on the same semiconductor substrate without using an SO substrate. At the same time, the first and second semiconductor layers are prevented from forming on the well that is heavily doped and crystal defects of the first and second semiconductor layers can be reduced. Further when the second semiconductor layer is deposited on the first semiconductor layer, it is possible to bring the first semiconductor layer into contact with an etching fluid or gas through a second trench. It is therefore possible to remove the first semiconductor layer with the second semiconductor layer remaining unremoved, and to provide the buried insulating layer embedded in the cavity under the second semiconductor layer. In addition, by embedding a support member in a first trench, even when the cavity is formed under the second semiconductor layer, it becomes possible to support the second semiconductor layer on the semiconductor substrate. It is therefore possible to realize a SOC satisfying various requirements such as high-breakdown-voltage, low power consumption, low voltage drive and high speed on a single chip while manufacturing cost is prevented from increasing. Reliability of an SOI transistor can thus be improved.

According to a fourth aspect of the invention, a method for manufacturing a semiconductor device includes: forming a P well on a semiconductor substrate; forming an N well on the semiconductor substrate; forming a first semiconductor layer on the semiconductor substrate avoiding the P well and the N well; forming a second semiconductor layer having a smaller etching rate than an etching rate of the first semiconductor layer on the first semiconductor layer; forming a first trench on the semiconductor substrate through the second semiconductor layer and the first semiconductor layer to expose a part of the semiconductor substrate; forming a support member embedded in the first trench on the semiconductor substrate to cover the second semiconductor layer; forming a second trench on the semiconductor substrate through the second semiconductor layer and the first semiconductor layer to expose a part of an end part of the first semiconductor layer; selectively etching the first semiconductor layer through the second trench to form a cavity under the second semiconductor layer by removing the first semiconductor layer; forming a buried insulating layer embedded in the cavity; forming a first gate electrode on the second semiconductor layer through a first gate insulating film, the first gate electrode having a first side and a second side; forming a source layer and a drain layer on the second semiconductor layer, the source layer being arranged on the first side of the first gate electrode and a drain layer being arranged on the second side of the first gate electrode; forming a second gate electrode on the P well through a second gate insulating film, the second gate electrode having a third side and a fourth side; forming an N-type source layer and an N-type drain layer on the P well, the N-type source layer being arranged on the third side of the second gate electrode and the N-type drain layer being arranged on the fourth side of the second gate electrode; forming a third gate electrode on the N well through a third gate insulating film, the third gate electrode having a fifth side and a sixth side; and forming a P-type source layer and a P-type drain layer on the N well, the P-type source layer being arranged on the fifth side of the third gate electrode and the P-type drain layer being arranged on the sixth side of the third gate electrode.

Thereby, it becomes possible to form an SOI structure and a bulk structure on the same semiconductor substrate without using an SOI substrate while a CMOS circuit is configured and a crystal defect of the semiconductor layer is reduced. The invention thus can prevent manufacturing cost from increasing, and elements having various functions with excellent characteristics can be formed on the same chip.

In order to solve the above-mentioned problem, a semiconductor device according to a fifth aspect of the invention includes a semiconductor substrate, a well formed on the semiconductor substrate, a semiconductor layer formed on the well by epitaxial growth, a buried insulating layer embedded between the semiconductor substrate and the semiconductor layer, a first field-effect transistor formed on the semiconductor layer, and a second field-effect transistor formed on the well, including a channel having a same conductivity type as that of the first field-effect transistor.

Accordingly, it becomes possible to form an SOI structure in a part of the region of the semiconductor substrate without using an SOI substrate. The SOI structure and a bulk structure can thus be formed on the same semiconductor substrate. At the same time, since the SOI structure and the bulk structure can receive the same substrate potential, unintentional back bias that may apply to an SOI transistor is prevented. This makes it possible to mount both an SOI transistor and a high-breakdown-voltage transistor on the same semiconductor substrate without using an SOI substrate while manufacturing cost is prevented from increasing. Accordingly, a SOC is realized.

Further, according to a sixth aspect of the invention, a semiconductor device includes a semiconductor substrate, a P well formed on the semiconductor substrate, an N well formed on the semiconductor substrate, a semiconductor layer formed on the P well and the N well by epitaxial growth, a buried insulating layer embedded between the semiconductor substrate and the semiconductor layer, a first N-channel field-effect transistor formed on the semiconductor layer on the P well, a second N-channel field-effect transistor formed on the P well, a first P-channel field-effect transistor formed on the semiconductor layer on the N well, and a second P-channel field-effect transistor formed on the N well.

Thereby, it becomes possible to form an SOI structure and a bulk structure on the same semiconductor substrate without using an SOI substrate while a CMOS circuit is configured and unintentional back bias that may apply to an SOI transistor is prevented. The invention thus can prevent manufacturing cost from increasing, and elements having various functions with excellent characteristics can be formed on the same chip.

According to a seventh aspect of the invention, a method for manufacturing a semiconductor device includes forming a well on a semiconductor substrate, forming a first semiconductor layer on the well, forming a second semiconductor layer having a smaller etching rate than that of the first semiconductor layer on the first semiconductor layer, forming a support member supporting the second semiconductor layer on the semiconductor substrate, forming an exposing part to expose at least a part of the first semiconductor layer from the second semiconductor layer, selectively etching the first semiconductor layer through the exposing part to form a cavity under the second semiconductor layer by removing the first semiconductor layer, forming a buried insulating layer embedded in the cavity through the exposing part, forming a first field-effect transistor on the semiconductor layer, and forming a second field-effect transistor on the well, including a channel having a same conductivity type as a conductivity type of the first field-effect transistor.

Accordingly, it becomes possible to mount an SOI element and a bulk element can thus be formed on the same semiconductor substrate without using an SOI substrate. At the same time, since an SOI transistor and a bulk transistor can receive the same substrate potential, unintentional back bias that may apply to the SOI transistor is prevented. Further when the second semiconductor layer is deposited on the first semiconductor layer, it is possible to bring the first semiconductor layer into contact with an etching fluid or gas through a second trench. It is therefore possible to remove the first semiconductor layer with the second semiconductor layer remaining unremoved, and to provide the buried insulating layer embedded in the cavity under the second semiconductor layer. In addition, by embedding a support member in a first trench, even when the cavity is formed under the second semiconductor layer, it becomes possible to support the second semiconductor layer on the semiconductor substrate. It is therefore possible to realize a SOC satisfying various requirements such as high-breakdown-voltage, low power consumption, low voltage drive and high speed on a single chip while manufacturing cost is prevented from increasing.

According to an eighth aspect of the invention, a method for manufacturing a semiconductor device includes forming a P well on a semiconductor substrate, forming an N well on the semiconductor substrate, forming a first semiconductor layer on the P well and the N well, forming a second semiconductor layer having a smaller etching rate than that of the first semiconductor layer on the first semiconductor layer, forming a first trench on the semiconductor substrate through the second semiconductor layer and the first semiconductor layer to expose a part of the semiconductor substrate, forming a support member embedded in the first trench on the semiconductor substrate to cover the second semiconductor layer, forming a second trench on the semiconductor substrate through the second semiconductor layer and the first semiconductor layer to expose a part of an end part of the first semiconductor layer, selectively etching the first semiconductor layer through the second trench to form a cavity under the second semiconductor layer by removing the first semiconductor layer, forming a buried insulating layer embedded in the cavity, forming a first N-channel field-effect transistor on the semiconductor layer on the P well, forming a second N-channel field-effect transistor on the P well, forming a first P-channel field-effect transistor on the semiconductor layer on the N well; and forming a second P-channel field-effect transistor on the N well.

Thereby, it becomes possible to form an SOI structure and a bulk structure on the same semiconductor substrate without using an SOI substrate while a CMOS circuit is configured and unintentional back bias that may apply to an SOI transistor is prevented. The invention thus can prevent manufacturing cost from increasing, and elements having various functions with excellent characteristics can be formed on the same chip.

In order to solve the above-mentioned problem, a semiconductor device according to a ninth aspect of the invention includes: a semiconductor substrate isolated by a LOCOS structure; a semiconductor layer formed inside of an active region defined by the LOCOS structure by epitaxial growth through a buried insulating layer; an STI structure arranged between the semiconductor layer and the LOCOS structure; a gate electrode formed on the semiconductor layer so that an end part of the gate electrode reaches the STI structure, the gate electrode having a first side and a second side; and a source layer and a drain layer formed on the semiconductor layer, the source layer being arranged on the first side of the gate electrode and a drain layer being arranged on the second side of the gate electrode.

Accordingly, an SOI transistor is formed on the semiconductor layer without using an SOI substrate. Besides, when the semiconductor substrate is isolated by the LOCOS structure and the STI structure, the gate electrode can be arranged avoiding the border between the LOCOS structure and the STI structure. It is therefore possible to realize a transistor with low power consumption and high speed while manufacturing cost is prevented from increasing. At the same time, a leak current from the gate electrode to the semiconductor substrate, and deterioration of reliability of the gate insulating film are prevented.

Further, according to a tenth aspect of the invention, a semiconductor device includes: a semiconductor substrate isolated by a LOCOS structure; a semiconductor layer formed inside of a first active region defined by the LOCOS structure by epitaxial growth through a buried insulating layer; an STI structure arranged between the semiconductor layer and the LOCOS structure; a first gate electrode formed on the semiconductor layer so that an end part of the first gate electrode reaches the STI structure, the first gate electrode having a first side and a second side; a first source layer and a first drain layer formed on the semiconductor layer, the first source layer being arranged on the first side of the first gate electrode and the first drain layer being arranged on the second side of the first gate electrode; a second gate electrode formed in a second active region defined by the LOCOS structure on the semiconductor substrate, the second gate electrode having a third side and a fourth side; and a second source layer and a second drain layer formed on the semiconductor substrate, the second source layer being arranged on the third side of the second gate electrode and the second drain layer being arranged on the fourth side of the second gate electrode.

Accordingly, it becomes possible to form an SOI structure in a part of the region of the semiconductor substrate without using an SOI substrate. An SOI structure and a bulk structure can thus be formed on the same semiconductor substrate. At the same time, the gate electrode is arranged avoiding the border between the LOCOS structure and the STI structure while an isolation breakdown voltage is improved. This makes it possible to realize a SOC as both an SI transistor and a high-breakdown-voltage transistor can be mounted on the same semiconductor substrate without using an SOI substrate while manufacturing cost is prevented from increasing. In addition, in a case where the semiconductor substrate is isolated by the LOCOS structure and the STI structure, a leak current from the gate electrode to the semiconductor substrate, and deterioration of reliability of the gate insulating film are prevented.

According to an eleventh aspect of the invention, a method for manufacturing a semiconductor device includes: forming a LOCOS structure to isolate a semiconductor substrate; a first semiconductor layer on the semiconductor substrate isolated by the LOCOS structure; forming a second semiconductor layer having a smaller etching rate than an etching rate of the first semiconductor layer on the first semiconductor layer; forming a first trench on the semiconductor substrate through the second semiconductor layer and the first semiconductor layer to expose a part of the semiconductor substrate; forming a support member embedded in the first trench on the semiconductor substrate to cover the second semiconductor layer; forming a second trench on the semiconductor substrate through the second semiconductor layer and the first semiconductor layer to expose a part of an end part of the first semiconductor layer; selectively etching the first semiconductor layer through the second trench to form a cavity under the second semiconductor layer by removing the first semiconductor layer; forming a buried insulating layer embedded in the cavity; forming an STI structure having the first trench filled with the support member by making the support member thin; forming a gate electrode on the second semiconductor layer so that an end part of the gate electrode reaches the STI structure, the gate electrode having a first side and a second side; and forming a source layer and a drain layer on the second semiconductor layer, the source layer being arranged on the first side of the gate electrode and the drain layer being arranged on the second side of the gate electrode.

Accordingly, it is possible to remove the first semiconductor layer with the second semiconductor layer remaining unremoved, resulting in forming a cavity under the second semiconductor layer. At the same time, by covering the second semiconductor layer with the support member, even when the cavity is formed under the second semiconductor layer, it becomes possible to support the second semiconductor layer on the semiconductor substrate. Further, by forming the second trench on the semiconductor substrate through the second semiconductor layer and the first semiconductor layer to expose a part of an end part of the first semiconductor layer, when the second semiconductor layer is deposited on the first semiconductor layer, it is also possible to bring the first semiconductor layer into contact with an etching gas or fluid. It is therefore possible to remove the first semiconductor layer with the second semiconductor layer remaining unremoved, and to embed the buried insulating layer in the cavity under the second semiconductor layer. Furthermore, because the support member is embedded in the first trench after the first trench is formed on the semiconductor substrate through the second semiconductor layer and the first semiconductor layer, even when the first semiconductor layer is removed, the support member can support the second semiconductor layer on the semiconductor substrate. Therefore, the STI structure arranged along inside of the LOCOS structure can be formed while preventing a manufacturing process from becoming complicated. At the same time, when the semiconductor substrate is isolated by the LOCOS structure and the STI structure, the gate electrode can be arranged avoiding the border between the LOCOS structure and the STI structure. Consequently, the method can provide the second semiconductor layer on the buried insulating layer while reducing defect occurrences of the second semiconductor layer. Besides, it is possible to achieve insulation between the second semiconductor layer and the semiconductor substrate without harming the quality of the second semiconductor layer. At the same time, a leak current from the gate electrode to the semiconductor substrate, and deterioration of reliability of the gate insulating film are prevented. As a result, it becomes possible to form an SOI transistor on the second semiconductor layer and improve quality of the SOI transistor while manufacturing cost is prevented from increasing.

According to a twelfth aspect of the invention, a method for manufacturing a semiconductor device includes: forming a LOCOS structure to isolate a semiconductor substrate; forming a first semiconductor layer in a first region on the semiconductor substrate isolated by the LOCOS structure; forming a second semiconductor layer having a smaller etching rate than an etching rate of the first semiconductor layer on the first semiconductor layer; forming a first trench on the semiconductor substrate through the second semiconductor layer and the first semiconductor layer to expose a part of the semiconductor substrate; forming a support member embedded in the first trench on the semiconductor substrate to cover the second semiconductor layer; forming a second trench on the semiconductor substrate through the second semiconductor layer and the first semiconductor layer to expose a part of an end part of the first semiconductor layer; selectively etching the first semiconductor layer through the second trench to form a cavity under the second semiconductor layer by removing the first semiconductor layer; forming a buried insulating layer embedded in the cavity; forming an STI structure having the first trench filled with the support member by making the support member thin; forming a first gate electrode on the second semiconductor layer so that an end part of the first gate electrode reaches the STI structure, the first gate electrode having a first side and a second side; forming a first source layer and a first drain layer on the second semiconductor layer, the first source layer being arranged on the first side of the first gate electrode and the first drain layer being arranged on the second side of the first gate electrode; forming a second gate electrode in a second region on the semiconductor substrate isolated by the LOCOS structure, the second gate electrode having a third side and a fourth side; and forming a second source layer and a second drain layer formed on the semiconductor substrate, the second source layer being arranged on the third side of the second gate electrode and the second drain layer being arranged on the fourth side of the second gate electrode. Consequently, the method can provide an SOI structure in a part of the region isolated by the STI structure on the semiconductor substrate as well as the bulk structure in other part of the region isolated by the LOCOS structure on the semiconductor substrate while reducing defect occurrences of the second semiconductor layer. Thereby, it becomes possible to form the SOI structure and the bulk structure on the same semiconductor substrate without using an SOI substrate, while an isolation breakdown voltage is improved and a leak current from the gate electrode to the semiconductor substrate, and deterioration of reliability of the gate insulating film are prevented. As a result, it becomes possible to mount both an SOI transistor and a high-breakdown-voltage transistor on the sa me semiconductor substrate and improve reliability of the SOI transistor and the high-breakdown-voltage transistor while manufacturing cost is prevented from increasing.

### BRIEF DESCRIPTION OF THE DRAWINGS

The invention will be described with reference to the accompanying drawings, wherein like numbers reference like elements.

FIG. 1 is a plan view illustrating a layout structuring a semiconductor device according to a first embodiment of the invention.

FIGS. 2A through 2D are sectional views illustrating a method for manufacturing the semiconductor device according to the first embodiment of the invention.

FIGS. 3A to 3C are diagrams illustrating the method for manufacturing the semiconductor device according to the first embodiment of the invention.

FIGS. 4A through 4C are sectional views illustrating the method for manufacturing the semiconductor device according to the first embodiment of the invention.

FIG. 5 is a plan view illustrating a layout structuring a semiconductor device according to a second embodiment of the invention.

FIGS. 6A through 6D are sectional views illustrating a method for manufacturing the semiconductor device according to the second embodiment of the invention.

FIGS. 7A to 7C are diagrams illustrating the method for manufacturing the semiconductor device according to the second embodiment of the invention.

FIGS. 8A through 8C are sectional views illustrating the method for manufacturing the semiconductor device according to the second embodiment of the invention.

FIGS. 9A through 9D are sectional views illustrating a method for manufacturing a semiconductor device according to a third embodiment of the invention.

FIGS. 10A to 10C are diagrams illustrating the method for manufacturing the semiconductor device according to the third embodiment of the invention.

FIGS. 11A and 11B are sectional views illustrating the method for manufacturing the semiconductor device according to the third embodiment of the invention.

FIGS. 12A through 12C are diagrams illustrating the method for manufacturing the semiconductor device according to the third embodiment of the invention.

### DESCRIPTION OF EXEMPLARY EMBODIMENTS

A semiconductor device and a manufacturing method thereof according to embodiments of the invention will now be described with reference to the accompanying drawings.

### First Embodiment

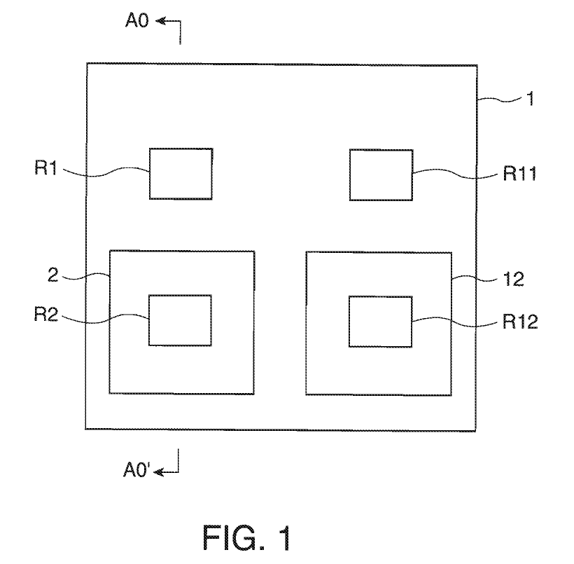

FIG. 1 is a plan view showing a layout structuring a semiconductor device according to a first embodiment of the invention.

As shown in FIG. 1, a P well 2 and an N well 12 are formed on a semiconductor substrate 1. On the semiconductor substrate 1, SOI forming regions R1 and R11 are arranged avoiding the P well 2 and the N well 12 while bulk regions R2 and R12 are arranged on the P well 2 and the P well 12, respectively. As the semiconductor substrate 1 here, a semiconductor wafer without impurity doping or a semiconductor wafer with impurity doped at low concentration can be used.

On the SOI forming regions R1 and R11, a semiconductor layer arranged on the semiconductor substrate 1 is formed by epitaxial growth, and a buried insulating layer is embedded between the semiconductor substrate 1 and the semiconductor layer. Additionally, an N-channel field-effect SOI transistor and a P-channel field-effect SOI transistor are respectively formed on the SOI forming regions R1 and R11. On the other hand, an N-channel field-effect bulk transistor and a P-channel field-effect bulk transistor are respectively formed on the bulk regions R2 and R12.

A semiconductor layer is thus prevented from being formed by epitaxial growth on the P well 2 and the N well 12 that are heavily doped, and a crystal defect of the semiconductor layer formed on the SOI forming regions R1 and R11 is reduced. Thereby, it becomes possible to form the SOI structure and the bulk structure on the same semiconductor substrate 1 without using an SOI substrate while a CMOS circuit is configured and a crystal defect of the semiconductor layer arranged on the SOI forming regions R1 and R11 is reduced. The invention thus can prevent manufacturing cost from increasing, and elements having various functions with excellent characteristics can be formed on the same chip.

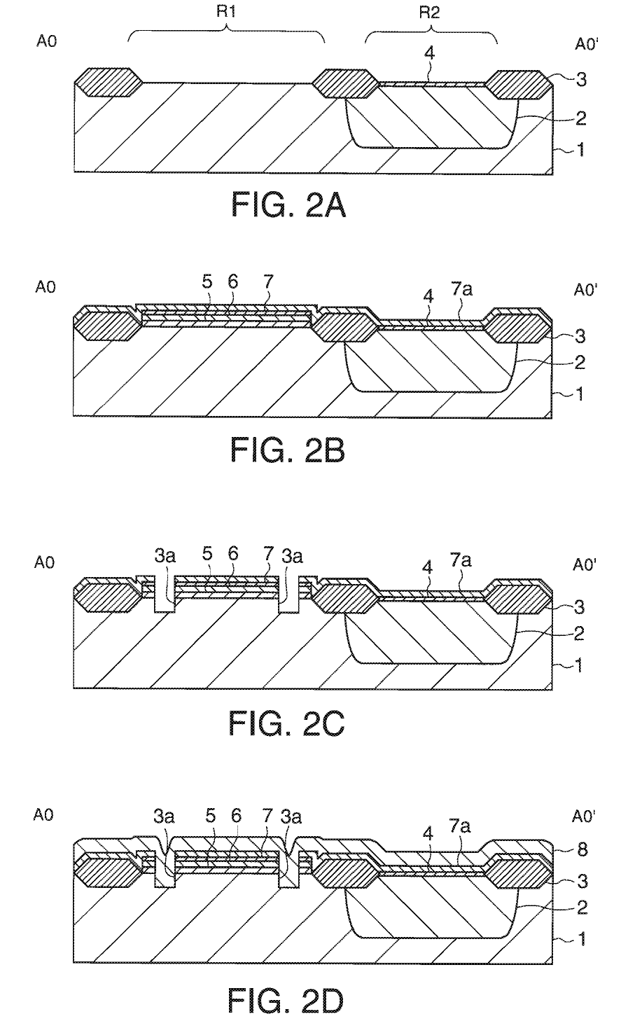

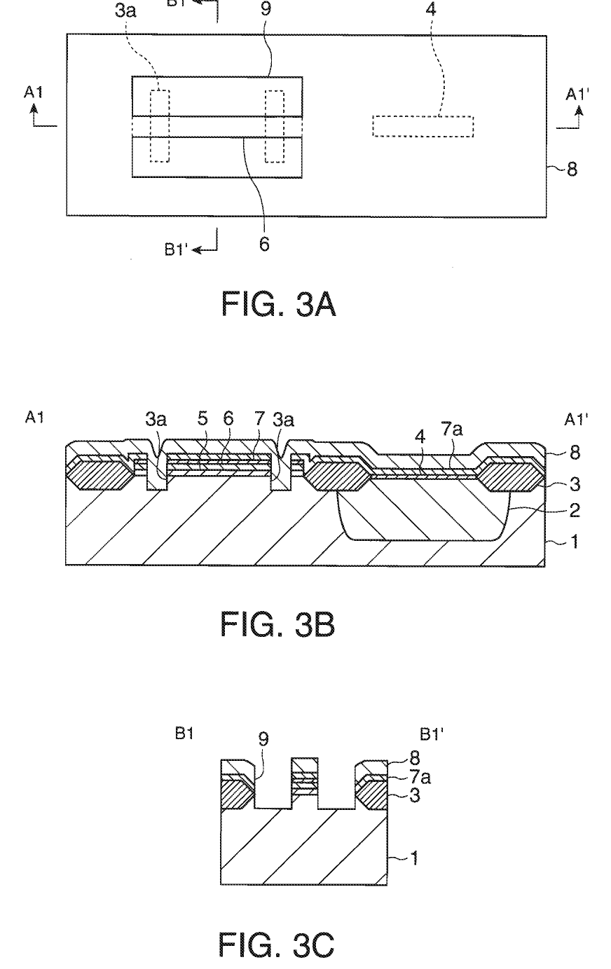

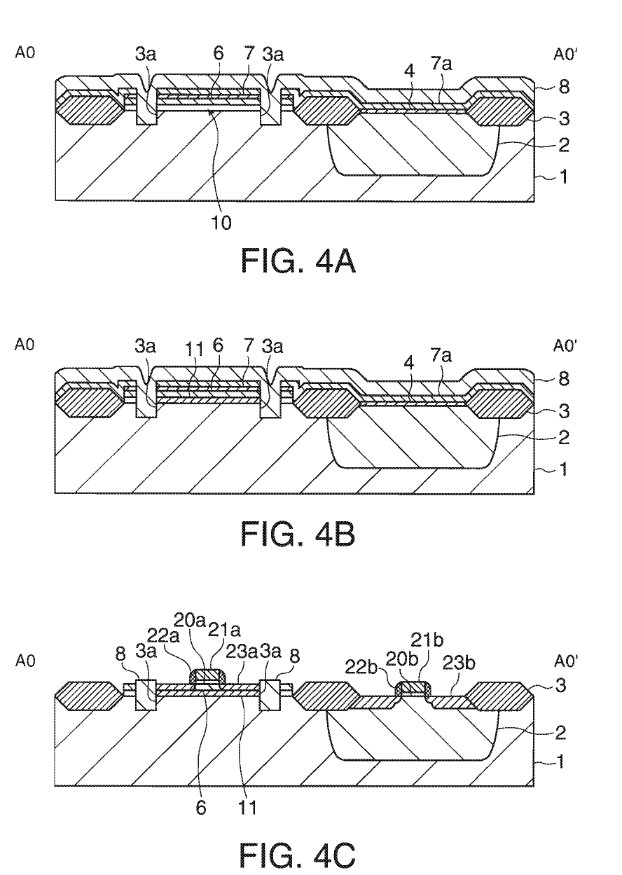

FIGS. 2A through 2D and FIGS. 4A through 4C are sectional views along lines A0 to A0′ of FIG. 1 showing the method for manufacturing a semiconductor device according to the first embodiment of the invention. FIG. 3A is a diagram showing a portion of the SI forming region R1 and the bulk region R2 (left half of FIG. 1) cut out of FIG. 1 that is a plan view showing the method for manufacturing the semiconductor device according to the first embodiment of the invention. FIG. 3B is a sectional view along A1 to A1′ of FIG. 3A, and FIG. 3C is a sectional view along B1 to B1′ of FIG. 3A.

In FIG. 2A, the SOI forming regions R1 and R11, and the Bulk regions R2 and R12 are formed on the semiconductor substrate 1. After ion implantation of an impurity such as B and BF₂ is selectively performed to the semiconductor substrate 1, thermal oxidation of the semiconductor substrate 1 is performed so as to form the P well 2 thereon. Similarly, after ion implantation of an impurity such as As and P is selectively performed to the semiconductor substrate 1, thermal oxidation of the semiconductor substrate 1 is performed so as to form the N well 12 thereon as shown in FIG. 1. Note that as a material for the semiconductor substrate 1, for example, Si, Ge, SiGe, SiC, SiSn, PbS, GaAs, InP, GaP, GaN or ZnSe can be used.

Then, after a pad oxide film 4 is formed on the semiconductor substrate 1 by thermal oxidation of the semiconductor substrate 1, an anti-oxidation film is deposited by a method such as chemical vapor deposition (CVD). As the anti-oxidation film, a silicon nitride film may be used, for example. Then, by patterning the anti-oxidation film and selectively oxidizing the semiconductor substrate 1 by using the patterned anti-oxidation film as a mask, a LOCOS structure 3 is formed on the semiconductor substrate 1 so as to isolate the SOI forming regions R1 and R2, and the bulk regions R2 and R12. As the LOCOS method, a recessed LOCOS (a method performing LOCOS oxidation to the semiconductor substrate 1 which is slightly etched by dry-etching after forming the pad oxide film 4 and the anti-oxidation film, and patterning the anti-oxidation film) can be used. Consequently, a difference in level between the surface of the semiconductor substrate 1 and the surface of the LOCOS structure 3 is reduced. Here, the SOI forming regions R1 and R11 are arranged on the semiconductor substrate 1 while the bulk region R2 is arranged on the P well 2 and the bulk region R12 is arranged on the N well 12. Then, the pad oxide film 4 is exposed by removing the anti-oxide film through etching The pad oxide film 4 is patterned by photolithography and an etching technique so as to expose the semiconductor substrate 1 in the SOI forming regions R1 and R11 by removing the pad oxide film 4 on the SOI forming regions R1 and R11 while the pad oxide film 4 on the bulk regions R2 and R12 remain.

Subsequently, as shown in FIG. 2B, a first semiconductor layer 5 and a second semiconductor layer 6 are sequentially and selectively formed on the SOI forming regions R1 and R11 on the semiconductor substrate 1 by epitaxial growth using the pad oxide film 4 as a mask. For the first semiconductor layer 5, a material whose selectivity ratio for etching is larger than those of the semiconductor substrate 1 and the second semiconductor layer 6 can be used. The materials for the first semiconductor layer 5 and the second semiconductor layer 6 can be selected and combined from Si, Ge, SiGe, SiC, SiSn, PbS, GaAs, InP, GaP, GaN and ZnSe, for example. Particularly, if the semiconductor substrate 1 is made of Si, it is preferable that the first semiconductor layer 5 be made of SiGe, while the second semiconductor layer 6 be made of Si. Accordingly, it is possible to achieve lattice matching between the first semiconductor layer 5 and the second semiconductor layer 6, and also to ensure the selectivity ratio between the first semiconductor layer 5 and the second semiconductor layer 6 for etching. Then, an underlying oxide film 7 is formed on the surface of the second semiconductor layer 6 by thermal oxidation of the second semiconductor layer 6. In the thermal oxidation at this time, it is preferable to be performed at a low temperature not to diffuse the epitaxially grown constituent of the first semiconductor layer 5 such as 750 degrees centigrade or less. Then, an anti-oxidation film 7a is deposited on the underlying oxide film 7 by CVD or the like. As the anti-oxidation film, a silicon nitride film may be used, for example. The film thickness of the first semiconductor layer 5 and the second semiconductor layer 6 is, for example, from about 1 to 200 nm, while the film thickness of the underlying oxide film 7 is, for example, about 10 nm, and the film thickness of the anti-oxidation film 7a is, for example, from about 100 to 200 nm.

Referring now to FIG. 2C, the anti-oxidation film 7a, the second semiconductor layer 6, the first semiconductor layer 5, and the semiconductor substrate 1 are patterned by photolithography and etching to form a trench 3a on the semiconductor substrate 1 through the second semiconductor layer 6 and the first semiconductor layer 5 to expose a part of the semiconductor substrate 1.

Next, as shown in FIG. 2D, a support member 8 is formed by CVD or the like to be embedded in the trench 3a and cover the anti-oxidation film 7a. As the support member 8, a silicon oxide film may be used, for example.

Subsequently, as shown in FIGS. 3A through 3C, the support member 8, the anti-oxidation film 7a, the second semiconductor layer 6, the first semiconductor layer 5, and the semiconductor substrate 1 are patterned by photolithography and etching to form a trench 9 to expose a part of the first semiconductor layer 5. When a part of the end portion of the first semiconductor layer 5 is exposed here, the rest of the end portions of the first semiconductor layer 5 and the bulk regions R2 and R12 can remain covered with the support member 8.

Subsequently, as shown in FIG. 4A, the first semiconductor layer 5 is etched and removed by contact with an etching gas or fluid through the trench 9 so as to form a cavity 10 between the semiconductor substrate 1 and the second semiconductor layer 6.

Here, since the trench 9 is formed besides the trench 3a, it is possible to bring the first semiconductor layer 5 under the second semiconductor layer 6 into contact with an etching gas or fluid, resulting in forming the cavity 10 between the semiconductor substrate 1 and the second semiconductor layer 6. Further, since the support member 8 is formed inside of the trench 3a, the second semiconductor layer 6 is supported by the support member 8 on the semiconductor substrate 1 even when the first semiconductor layer 5 is removed.

If the semiconductor substrate 1 and the second semiconductor layer 6 are made of Si, and the first semiconductor layer 5 is made of SiGe, it is preferable that hydrofluoric-nitric acid (a mixed liquid of hydrofluoric acid, nitric acid, and water) be used as the etching fluid for the first semiconductor layer 5. The selectivity ratio between Si and SiGe is thus about 1:100 to 1:1000. It is therefore possible to remove the first semiconductor layer 5 while overetching of the semiconductor substrate 1 and the second semiconductor layer 6 is prevented. As the etching fluid for the first semiconductor layer 5, hydrofluoric-nitric acid hydrogen peroxide, ammonia hydrogen peroxide, or hydrofluoric-acetic acid hydrogen peroxide can be used.

Additionally, in this embodiment, although the first semiconductor layer 5 is removed by forming the trench 3a, the support member and the trench 9 sequentially, the first semiconductor layer 5 can also be removed by forming the support member and the trench 9 without forming the trench 3a.

Next, as shown in FIG. 4B, a buried insulating layer 11 is formed in the cavity 10 located between the semiconductor substrate 1 and the second semiconductor layer 6 by thermal oxidation of the semiconductor substrate 1 and the second semiconductor layer 6. To form the buried insulating layer 11 by thermal oxidation of the semiconductor substrate 1 and the second semiconductor layer 6, it is preferable that low-temperature wet oxidation that provides reaction rate controlling be used to improve embedding properties. Here, after the buried insulating layer 11 is formed in the cavity 10, high-temperature annealing may be performed at 1100 degrees centigrade or more. It is therefore possible to reflow the buried insulating layer 11 to reduce stress on the buried insulating layer 11, and also to reduce the interface state at the boundary with the second semiconductor layer 6. Further, the buried insulating layer 11 may be formed to entirely fill the cavity 10 or leave part of the cavity 10 unfilled.

While the method referring to FIG. 4B provides the buried insulating layer 11 in the cavity 10 between the semiconductor substrate 1 and the second semiconductor layer 6 by thermal oxidation of the semiconductor substrate 1 and the second semiconductor layer 6, the buried insulating layer 11 can also be buried in the cavity 10 by providing an insulating film therein by CVD.

Next, as shown in FIG. 4C, after the buried insulating layer 11 is formed in the cavity 10 between the semiconductor substrate 1 and the second semiconductor layer 6, a buried insulating member is deposited over the whole surface by CVD or the like. As the buried insulating member, a silicon oxide film may be used, for example. After the buried insulating member and the support member 8 are made thin by chemical mechanical polishing (CMP) or the like, the anti-oxidation film 7a is etched by wet etching using thermal phosphoric acid so as to form an STI structure in which the surfaces of the pad oxide film 4 and the underlying oxide film 7 are exposed, the trench 3a is embedded with the support member 8, and the trench 9 is filled with the buried insulating member.

Then, by removing the pad oxide film 4 and the underlying oxide film 7, the surface of the second semiconductor layer 6 in the SOI forming regions R1 and R11 is exposed as well as the surface of the semiconductor substrate 1 in the bulk regions R2 and R12 is exposed. Subsequently, thermal oxidation is performed to the surfaces of the second semiconductor layer 6 and the semiconductor substrate 1 so as to form gate insulating films 20a and 20b respectively on the surfaces thereof. Then, a polycrystalline silicon layer is formed by CVD, for example, on the second semiconductor layer 6 and the semiconductor substrate 1 provided with the gate insulating films 20a and 20b. Then the polycrystalline silicon layer is patterned by photolithography and etching to form gate electrodes 21a and 21b respectively on the second semiconductor layer 6 and the semiconductor substrate 1.

Next, by ion-implanting one of impurities such as As, P, and B to the second semiconductor layer 6 and the semiconductor substrate 1 using the gate electrodes 21a and 21b as masks, a lightly doped drain (LDD) layer made of low concentration impurity implantation layers arranged on the both sides of each of the gate electrodes 21a and 21b are formed on the second semiconductor layer 6. After an insulating layer is formed on the second semiconductor layer 6 provided with the LDD layer by CVD or the like side walls 22a and 22b are formed respectively on the side walls of the gate electrodes 21a and 21b by etching back the insulating layer by anisotropic etching such as reactive ion etching (RIE). Then, one of impurities such as As, P, and B is ion-implanted to the second semiconductor layer 6 and the semiconductor substrate 1 using the gate electrodes 21a and 21b, and the side walls 22a and 22b as masks. Thus, source/drain layers 23a and 23b, which are high concentration impurity implanted layers and arranged on each of both sides of the side walls 22a and 22b respectively, are formed thereby on the second semiconductor layer 6 and the semiconductor substrate 1.

Accordingly, it is possible to form the SOI structure on the SOI forming regions R1 and R11, and the bulk structure on the bulk regions R2 and R12, without harming the crystal quality of the second semiconductor layer 6. Thereby, it becomes possible to form the SOI structure and the bulk structure on the same semiconductor substrate 1 without using an SOI substrate. This makes it possible to mount both an SOI transistor and a high-breakdown-voltage transistor on the same semiconductor substrate 1 while manufacturing cost is prevented from increasing.

For example, a logic circuit with a fully depleted SOI transistor is formed in the SOI forming regions R1 and R11 while a middle-breakdown-voltage analog circuit with a bulk transistor is formed in the bulk regions R2 and R12.

### Second Embodiment

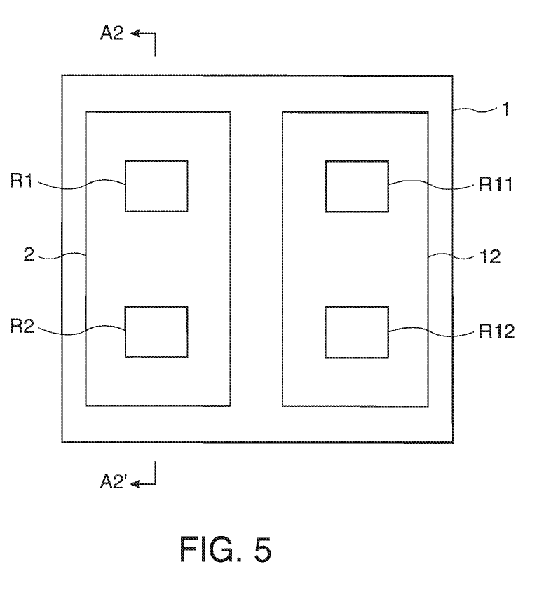

FIG. 5 is a plan view showing a layout structuring a semiconductor device according to a second embodiment of the invention.

As shown in FIG. 5, the P well 2 and the N well 12 are formed on the semiconductor substrate 1. Then, the SOI forming region R1 and the bulk region R2 are arranged on the P well 2 while the SOI forming region R11 and the bulk region R12 are arranged on the N well 12.

On the SOI forming regions R1 and R11, a semiconductor layer arranged on the semiconductor substrate 1 is formed by epitaxial growth, and a buried insulating layer is embedded between the semiconductor substrate 1 and the semiconductor layer. Further, an N-channel field-effect SOI transistor and a P-channel field-effect SOI transistor are respectively formed on the SOI forming regions R1 and R11. On the other hand, an N-channel field-effect bulk transistor and a P-channel field-effect bulk transistor are respectively formed on the bulk regions R2 and R12.

Accordingly, it becomes possible to form the SOI structure in a part of the region of a semiconductor substrate without using an SOI substrate. The SOI structure and the bulk structure can thus be formed on the same semiconductor substrate 1. In addition, the N-channel field-effect SOI transistor can receive the same substrate potential as that of the N-channel field-effect bulk transistor while the P-channel field-effect SOI transistor can receive the same substrate potential as that of the P-channel field-effect bulk transistor. Therefore, when the SOI structure and the bulk structure are mounted on the same semiconductor substrate 1, unintentional back bias that may apply to the N-channel field-effect SOI transistor and the P-channel field-effect SOI transistor is prevented. This makes it possible to mount both an SOI transistor and a high-breakdown-voltage transistor on the same semiconductor substrate 1 without using an SOI substrate while manufacturing cost is prevented from increasing. Accordingly, system on chip (SOC) is realized.

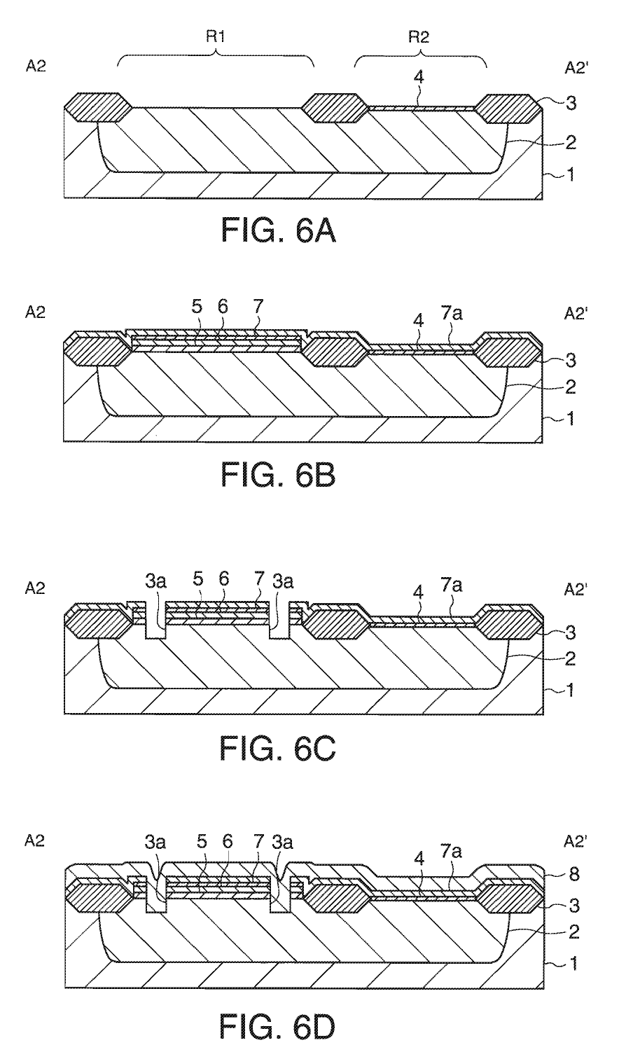

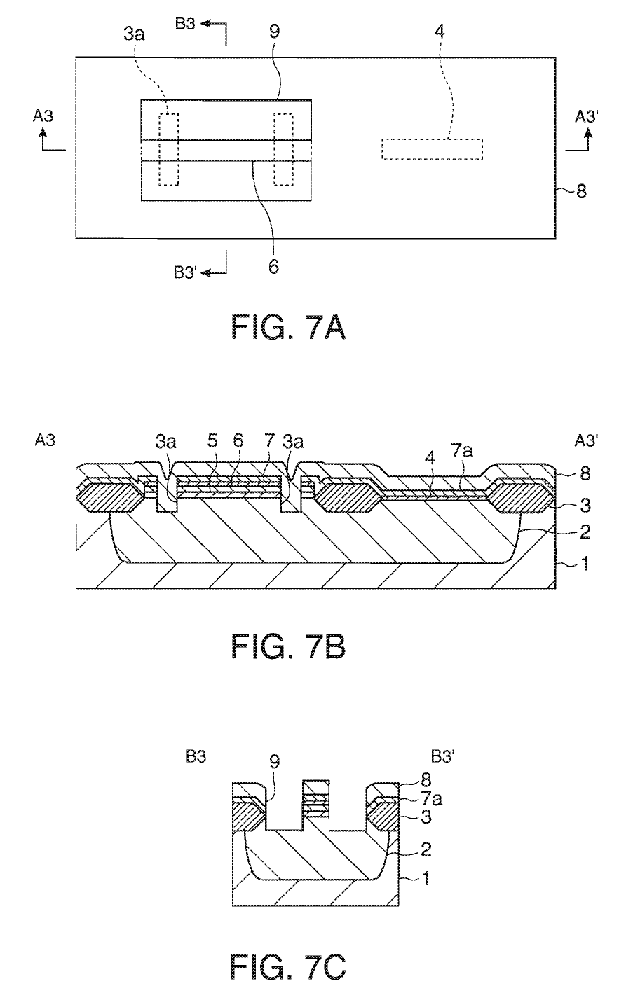

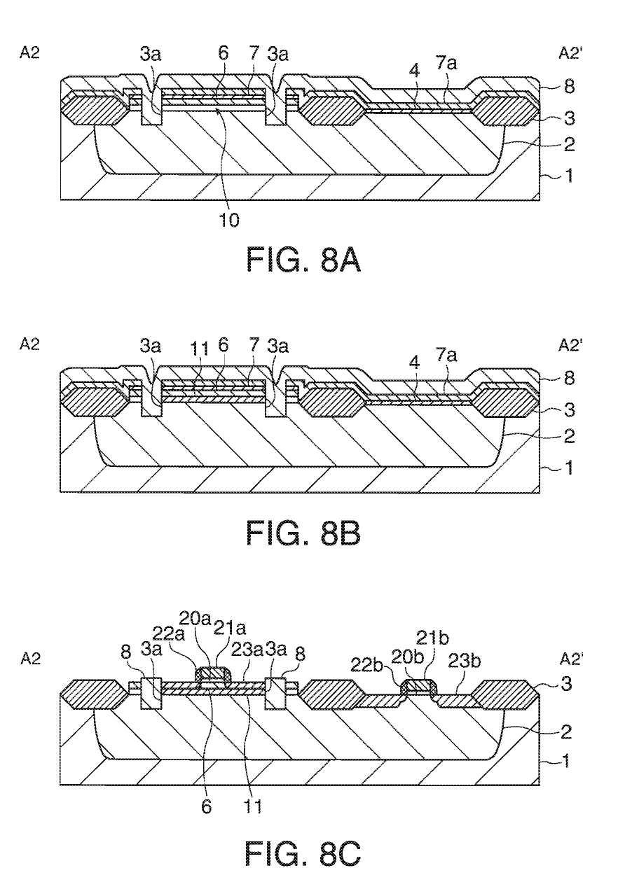

FIGS. 6A through 6D and FIGS. 8A through 8C are sectional views along lines A2 to A2′ of FIG. 5 showing the method for manufacturing a semiconductor device according to the second embodiment of the invention. FIG. 7A is a diagram showing a portion of the SOI forming region R1 and the bulk region R2 (left half of FIG. 5) cut out of FIG. 5 that is a plan view showing the method for manufacturing the semiconductor device according to the second embodiment of the invention. FIG. 7B is a sectional view along A3 to A3′ of FIG. 7A, and FIG. 7C is a sectional view along B3 to B3′ of FIG. 7A.

In FIG. 6A, the SOI forming regions R1 and R11, and the bulk regions R2 and R12 are formed on the semiconductor substrate 1. After ion implantation of one of impurities such as B and BF₂ is selectively performed to the semiconductor substrate 1, thermal oxidation of the semiconductor substrate 1 is performed so as to form the P well 2 thereon. Similarly, after ion implantation of one of impurities such as As and P is selectively performed to the semiconductor substrate 1, thermal oxidation of the semiconductor substrate 1 is performed so as to form the N well 12 thereon as shown in FIG. 5. Note that as a material for the semiconductor substrate 1, for example, Si, Ge, SiGe, SiC, SiSn, PbS, GaAs, InP, GaP, GaN or ZnSe can be used.

Then, after the pad oxide film 4 is formed on the semiconductor substrate 1 by thermal oxidation of the semiconductor substrate 1, an anti-oxidation film is deposited by a method such as CVD. As the anti-oxidation film, a silicon nitride film may be used, for example. Then, by patterning the anti-oxidation film and selectively oxidizing the semiconductor substrate 1 by using the patterned anti-oxidation film as a mask, the LOCOS structure 3 is formed on the semiconductor substrate 1 so as to isolate the SOI forming regions R1 and R2, and the bulk regions R2 and R12. As the LOCOS method, a recessed LOCOS (a method performing LOCOS oxidation to the semiconductor substrate 1 which is slightly etched by dry-etching after forming the pad oxide film 4 and the anti-oxidation film, and patterning the anti-oxidation film) can be used. Consequently, a difference in level between the surface of the semiconductor substrate 1 and the surface of the LOCOS structure 3 is reduced. Here, the SOI forming region R1 and the bulk region R2 are arranged on the P well 2 while the SOI forming region R11 and the bulk region R12 are arranged on the N well 12. Then, the pad oxide film 4 is exposed by removing the anti-oxide film through etching. The pad oxide film 4 is patterned by photolithography and an etching technique so as to expose the semiconductor substrate 1 in the SOI forming regions R1 and R11 by removing the pad oxide film 4 on the SOI forming regions R1 and R11 while the pad oxide film 4 on the bulk regions R2 and R12 remain.

Subsequently, as shown in FIG. 6B, the first semiconductor layer 5 and the second semiconductor layer 6 are sequentially and selectively formed on the SOI forming regions R1 and R11 on the semiconductor substrate 1 by epitaxial growth using the pad oxide film 4 as a mask. For the first semiconductor layer 5, a material whose selectivity ratio for etching is larger than those of the semiconductor substrate 1 and the second semiconductor layer 6 can be used. The materials for the first semiconductor layer 5 and the second semiconductor layer 6 can be selected and combined from Si, Ge, SiGe, SiC, SiSn, PbS, GaAs, InP, GaP, GaN and ZnSe, for example. Particularly if the semiconductor substrate 1 is made of Si, it is preferable that the first semiconductor layer 5 be made of SiGe, while the second semiconductor layer 6 be made of Si. Accordingly, it is possible to achieve lattice matching between the first semiconductor layer 5 and the second semiconductor layer 6, and also to ensure the selectivity ratio between the first semiconductor layer 5 and the second semiconductor layer 6 for etching. Then, the underlying oxide film 7 is formed on the surface of the second semiconductor layer 6 by thermal oxidation of the second semiconductor layer 6. In the thermal oxidation at this time, it is preferable to be performed at a low temperature not to diffuse the epitaxially grown constituent of the first semiconductor layer 5 such as 750 degrees centigrade or less. Then, the anti-oxidation film 7a is deposited on the underlying oxide film 7 by a method such as CVD. As the anti-oxidation film, a silicon nitride film may be used, for example. The film thickness of the first semiconductor layer 5 and the second semiconductor layer 6 is, for example, from about 1 to 200 nm, while the film thickness of the underlying oxide film 7 is, for example, about 10 nm, and the film thickness of the anti-oxidation film 7a is, for example, from about 100 to 200 nm.

Referring now to FIG. 6C, the anti-oxidation film 7a, the second semiconductor layer 6, the first semiconductor layer 5, and the semiconductor substrate 1 are patterned by photolithography and etching to form the trench 3a on the semiconductor substrate 1 through the second semiconductor layer 6 and the first semiconductor layer 5 to expose a part of the semiconductor substrate 1.

Next, as shown in FIG. 6D, the support member 8 is formed by CVD or the like to be embedded in the trench 3a and cover the anti-oxidation film 7a. As the support member 8, a silicon oxide film may be used, for example.

Subsequently, as shown in FIGS. 7A through 7C, the support member 8, the anti-oxidation film 7a, the second semiconductor layer 6, the first semiconductor layer 5, and the semiconductor substrate 1 are patterned by photolithography and etching to form the trench 9 to expose a part of the first semiconductor layer 5. When a part of the end portion of the first semiconductor layer 5 is exposed here, the rest of the end portions of the first semiconductor layer 5 and the bulk regions R2 and R12 can remain covered with the support member 8.

Subsequently, as shown in FIG. 8A, the first semiconductor layer 5 is etched and removed by contact with an etching gas or fluid through the trench 9 so as to form a cavity 10 between the semiconductor substrate 1 and the second semiconductor layer 6.

Here, since the trench 9 is formed besides the trench 3a, it is possible to bring the first semiconductor layer 5 under the second semiconductor layer 6 into contact with an etching gas or fluid, resulting in forming the cavity 10 between the semiconductor substrate 1 and the second semiconductor layer 6. Further, since the support member 8 is formed inside of the trench 3a, the second semiconductor layer 6 is supported by the support member 8 on the semiconductor substrate 1 even when the first semiconductor layer 5 is removed.

If the semiconductor substrate 1 and the second semiconductor layer 6 are made of Si, and the first semiconductor layer 5 is made of SiGe, it is preferable that hydrofluoric-nitric acid be used as the etching fluid for the first semiconductor layer 5. The selectivity ratio between Si and SiGe is thus about 1:100 to 1:1000. It is therefore possible to remove the first semiconductor layer 5 while overetching of the semiconductor substrate 1, and the second semiconductor layer 6 is prevented. As the etching fluid for the first semiconductor layer 5, hydrofluoric-nitric acid hydrogen peroxide, ammonia hydrogen peroxide, or hydrofluoric-acetic acid hydrogen peroxide can be used.

Additionally, in this embodiment, although the first semiconductor layer 5 is removed by forming the trench 3a, the support member and the trench 9 sequentially, the first semiconductor layer 5 can also be removed by forming the support member and the trench 9 without forming the trench 3a.

Next, as shown in FIG. 8B, the buried insulating layer 11 is formed in the cavity 10 located between the semiconductor substrate 1 and the second semiconductor layer 6 by thermal oxidation of the semiconductor substrate 1 and the second semiconductor layer 6. To form the buried insulating layer 11 by thermal oxidation of the semiconductor substrate 1 and the second semiconductor layer 6, it is preferable that low-temperature wet oxidation that provides reaction rate controlling be used to improve embedding properties. Here, after the buried insulating layer 11 is formed in the cavity 10, high-temperature annealing may be performed at 1100 degrees centigrade or more. It is therefore possible to reflow the buried insulating layer 11 to reduce stress on the buried insulating layer 11, and also to reduce the interface state at the boundary with the second semiconductor layer 6. Further, the buried insulating layer 11 may be formed to entirely fill the cavity 10 or leave part of the cavity 10 unfilled.

While the method referring to FIG. 8B provides the buried insulating layer 11 in the cavity 10 between the semiconductor substrate 1 and the second semiconductor layer 6 by thermal oxidation of the semiconductor substrate 1 and the second semiconductor layer 6, the buried insulating layer 11 can also be buried in the cavity 10 by providing an insulating film therein by CVD.

Next, as shown in FIG. 8C, after the buried insulating layer 11 is formed in the cavity 10 between the semiconductor substrate 1 and the second semiconductor layer 6, a buried insulating member is deposited over the whole surface by CVD or the like. As the buried insulating member, a silicon oxide film may be used, for example. After the buried insulating member and the support member 8 are made thin by CMP or the like, the anti-oxidation film 7a is etched by wet etching using thermal phosphoric acid so as to form an STI structure in which the surfaces of the pad oxide film 4 and the underlying oxide film 7 are exposed, the trench 3a is embedded with the support member 8, and the trench 9 is filled with the buried insulating member.

Then, by removing the pad oxide film 4 and the underlying oxide film 7, the surface of the second semiconductor layer 6 in the SOI forming regions R1 and R11 is exposed as well as the surface of the semiconductor substrate 1 in the bulk regions R2 and R12 is exposed. Subsequently, thermal oxidation is performed to the surfaces of the second semiconductor layer 6 and the semiconductor substrate 1 so as to form the gate insulating films 20a and 20b respectively on the surfaces thereof. Then, a polycrystalline silicon layer is formed by CVD, for example, on the second semiconductor layer 6 and the semiconductor substrate 1 provided with the gate insulating films 20a and 20b. Then the polycrystalline silicon layer is patterned by photolithography and etching to form gate electrodes 21a and 21b respectively on the second semiconductor layer 6 and the semiconductor substrate 1.

Next, by ion-implanting one of impurities such as As, P, and B to the second semiconductor layer 6 and the semiconductor substrate 1 using the gate electrodes 21a and 21b as masks, a LDD layer made of low concentration impurity implantation layers arranged on the both sides of each of the gate electrodes 21a and 21b are formed on the second semiconductor layer 6. After an insulating layer is formed on the second semiconductor layer 6 provided with the LDD layer by CVD or the like, the side walls 22a and 22b are formed respectively on the side walls of the gate electrodes 21a and 21b by etching back the insulating layer by anisotropic etching such as reactive ion etching (RIE). Then, one of impurities such as As, P, and B is ion-implanted to the second semiconductor layer 6 and the semiconductor substrate 1 using the gate electrodes 21a and 21b, and the side walls 22a and 22b as masks. Thus, source/drain layers 23a and 23b, which are high concentration impurity implanted layers and arranged on each of both sides of the side walls 22a and 22b respectively, are formed thereby on the second semiconductor layer 6 and the semiconductor substrate 1.

Accordingly, it is possible to form the SOI structure on the SOI forming regions R1 and R11, and the bulk structure on the bulk regions R2 and R12, without harming the crystal quality of the second semiconductor layer 6. Thereby, it becomes possible to form the SOI structure and the bulk structure on the same semiconductor substrate 1 without using an SOI substrate. This makes it possible to mount both an SOI transistor and a high-breakdown-voltage transistor on the same semiconductor substrate 1 while manufacturing cost is prevented from increasing.

For example, a logic circuit with a fully depleted SOI transistor is formed in the SOI forming regions R1 and R11 while a middle-breakdown-voltage analog circuit with a bulk transistor is formed in the bulk regions R2 and R12.

### Third Embodiment

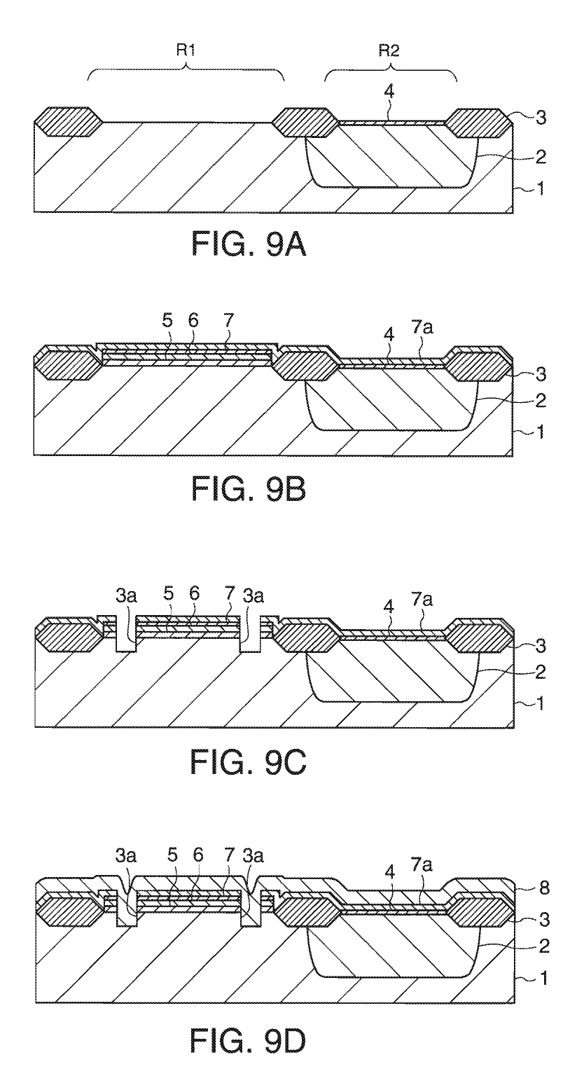

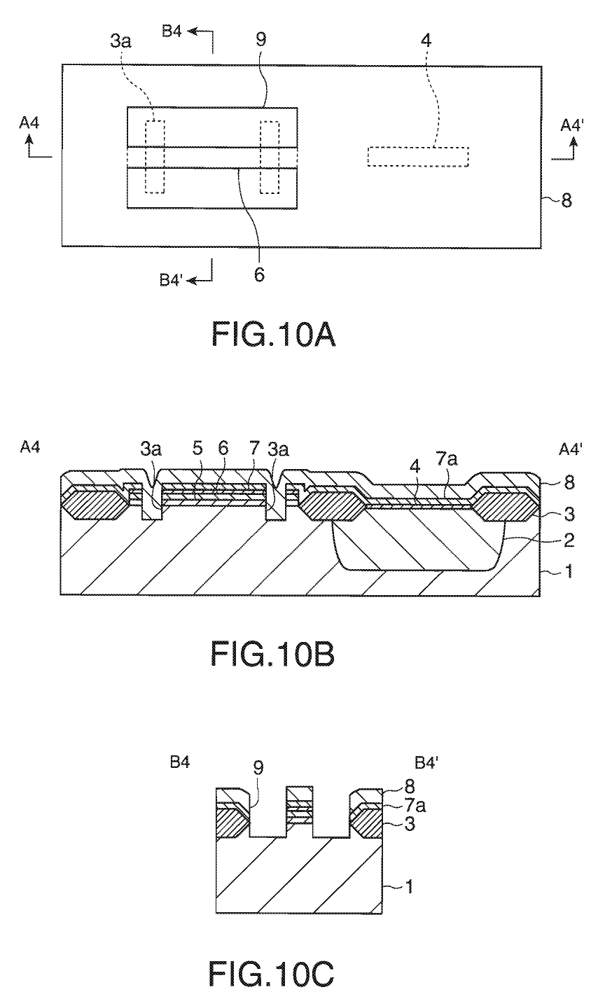

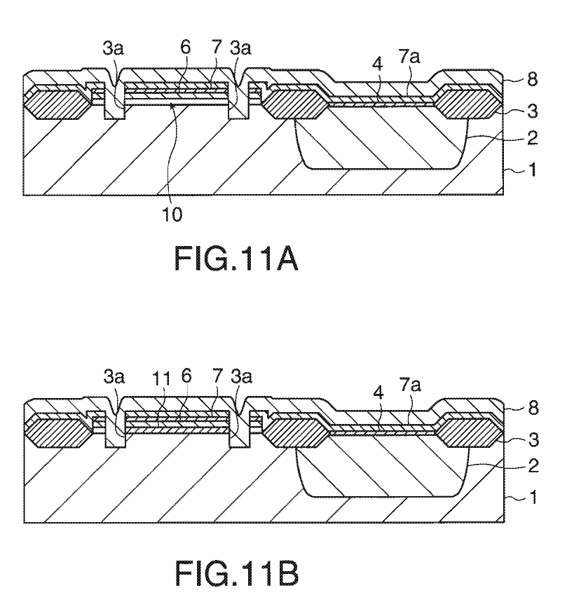

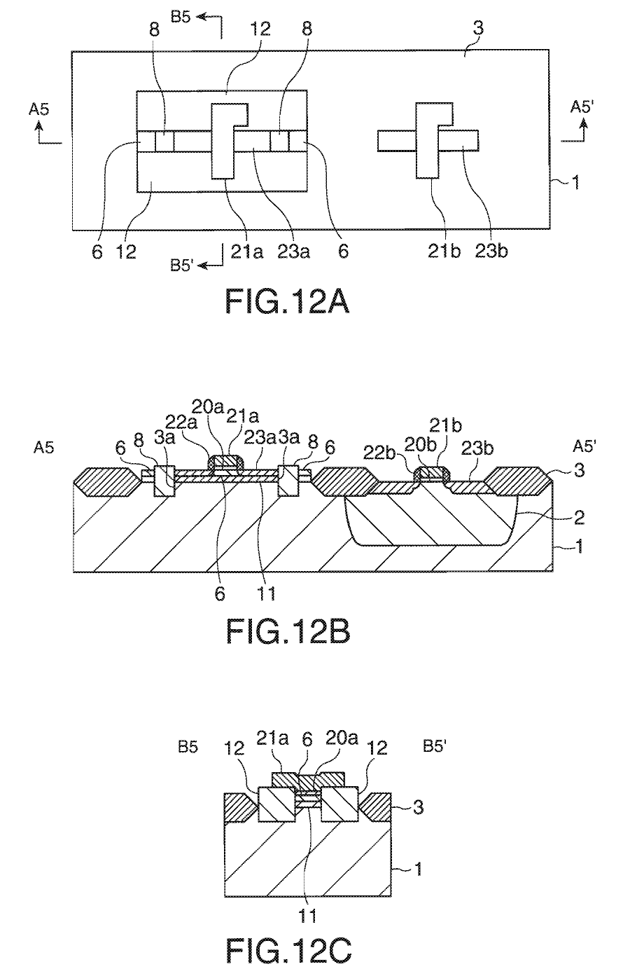

FIGS. 9A through 9D and FIGS. 11A and 11B are sectional views showing a method for manufacturing a semiconductor device according to a third embodiment of the invention. FIG. 10A is a plan view showing the method for manufacturing the semiconductor device according to the third embodiment of the invention, FIG. 10B is a sectional view along A4 to A4′ of FIG. 10A, and FIG. 10C is a sectional view along B4 to B4′ of FIG. 10A. FIG. 12A is a plan view showing the method for manufacturing the semiconductor device according to the third embodiment of the invention, FIG. 12B is a sectional view along A5 to A5′ of FIG. 12A, and FIG. 12C is a sectional view along B5 to B5′ of FIG. 12A.

In FIG. 9A, the SOI forming region R1 and the bulk region R2 are formed on the semiconductor substrate 1. After ion implantation of an impurity to the bulk region R2 by using photolithography and etching, thermal oxidation is performed to the semiconductor substrate 1 so as to form a well 2 in the bulk region R2. Note that as a material for the semiconductor substrate 1, for example, Si, Ge, SiGe, SiC, SiSn, PbS, GaAs, InP, GaP, GaN or ZnSe can be used. Then, after the pad oxide film 4 is formed on the semiconductor substrate 1 by thermal oxidation of the semiconductor substrate 1, an anti-oxidation film is deposited by CVD or the like. As the anti-oxidation film, a silicon nitride film may be used, for example. Then, by patterning the anti-oxidation film and selectively oxidizing the semiconductor substrate 1 by using the patterned anti-oxidation film as a mask, the LOCOS structure 3 is formed on the semiconductor substrate 1 so as to isolate the SOI forming region R1 and the bulk region R2. As the LOCOS method, a recessed LOCOS (a method performing LOCOS oxidation to the semiconductor substrate 1 which is slightly etched by dry-etching after forming the pad oxide film 4 and the anti-oxidation film, and patterning the anti-oxidation film) can be used. Consequently, a difference in level between the surface of the semiconductor substrate 1 and the surface of the LOCOS structure 3 is reduced. Then, the pad oxide film 4 is exposed by removing the anti-oxide film through etching. The pad oxide film 4 is patterned by photolithography and etching so as to expose the semiconductor substrate in the SO forming region R1 by removing the pad oxide film 4 on the SOI forming region R1 while the pad oxide film 4 on the bulk region R2 remain.

Subsequently, as shown in FIG. 9B, the first semiconductor layer 5 and the second semiconductor layer 6 are sequentially and selectively formed in the SOI forming region R1 on the semiconductor substrate 1 by epitaxial growth using the pad oxide film 4 as a mask. For the first semiconductor layer 5, a material whose etching rate is larger than those of the semiconductor substrate 1 and the second semiconductor layer 6 can be used. The materials for the first semiconductor layer 5 and the second semiconductor layer 6 can be selected and combined from Si, Ge, SiGe, SiC, SiSn, PbS, GaAs, InP, GaP, GaN and ZnSe, for example. Particularly if the semiconductor substrate 1 is made of Si, it is preferable that the first semiconductor layer 5 be made of SiGe, while the second semiconductor layer 6 be made of Si. Accordingly, it is possible to achieve lattice matching between the first semiconductor layer 5 and the second semiconductor layer 6, and also to ensure the selectivity ratio between the first semiconductor layer 5 and the second semiconductor layer 6 for etching. In addition, as the first semiconductor layer 5, a polycrystalline semiconductor layer, an amorphous semiconductor layer, or a porous semiconductor layer may be used other than a single crystal semiconductor layer. The first semiconductor layer 5 may be replaced with gamma-aluminum oxide or other metal oxide films on which a single crystal semiconductor layer can be deposited by epitaxial growth. Then, the underlying oxide film 7 is formed on the surface of the second semiconductor layer 6 by thermal oxidation of the second semiconductor layer 6. In the thermal oxidation at this time, it is preferable to be performed at a low temperature not to diffuse the epitaxially grown constituent of the first semiconductor layer 5 such as 750 degrees centigrade or less. Then, the anti-oxidation film 7a is deposited on the underlying oxide film 7 by a method such as CVD. As the anti-oxidation film, a silicon nitride film may be used, for example. The film thickness of the first semiconductor layer 5 and the second semiconductor layer 6 is, for example, from about 1 to 200 nm, while the film thickness of the underlying oxide film 7 is, for example, about 10 nm, and the film thickness of the anti-oxidation film 7a is, for example, from about 100 to 200 nm.

Referring now to FIG. 9C, the anti-oxidation film 7a, the second semiconductor layer 6, the first semiconductor layer 5, and the semiconductor substrate 1 are patterned by photolithography and etching to form the trench 3a on the semiconductor substrate 1 through the second semiconductor layer 6 and the first semiconductor layer 5 to expose a part of the semiconductor substrate 1.

Next, as shown in FIG. 9D, the support member 8 is formed by CVD or the like to be embedded in the trench 3a and cover the anti-oxidation film 7a. As the support member 8, a silicon oxide film may be used, for example.

Subsequently, as shown in FIG. 10A through 10C, the support member 8, the anti-oxidation film 7a, the second semiconductor layer 6, the first semiconductor layer 5, and the semiconductor substrate 1 are patterned by photolithography and etching to form the trench 9 to expose a part of the first semiconductor layer 5.

Subsequently, as shown in FIG. 11A, the first semiconductor layer 5 is etched and removed by contact with an etching gas or fluid through the trench 9 so as to form a cavity 10 between the semiconductor substrate 1 and the second semiconductor layer 6.

Here, since the trench 9 is formed besides the trench 3a, it is possible to bring the first semiconductor layer 5 under the second semiconductor layer 6 into contact with an etching gas or fluid, resulting in forming the cavity 10 between the semiconductor substrate 1 and the second semiconductor layer 6. Further, since the support member 8 is formed inside of the trench 3a, the second semiconductor layer 6 is supported by the support member 8 on the semiconductor substrate 1 even when the first semiconductor layer 5 is removed.

If the semiconductor substrate 1 and the second semiconductor layer 6 are made of Si, and the first semiconductor layer 5 is made of SiGe, it is preferable that hydrofluoric-nitric acid be used as the etching fluid for the first semiconductor layer 5. The selectivity ratio between Si and SiGe is thus about 1:100 to 1:1000. It is therefore possible to remove the first semiconductor layer 5 while overetching of the semiconductor substrate 1 and the second semiconductor layer 6 is prevented. As the etching fluid for the first semiconductor layer 5, hydrofluoric-nitric acid hydrogen peroxide, ammonia hydrogen peroxide, or hydrofluoric-acetic acid hydrogen peroxide can be used. Further, before the first semiconductor layer 5 is etched and removed, the first semiconductor layer 5 may be made porous by anodic oxidation, for example, or may be made amorphous by ion implantation thereto. As the semiconductor substrate 1, a P-type semiconductor substrate may be used. Accordingly, the etching rate for the first semiconductor layer 5 can be increased and the etching area of the first semiconductor layer 5 can be expanded.

Next, as shown in FIG. 11B, the buried insulating layer 11 is formed in the cavity 10 located between the semiconductor substrate 1 and the second semiconductor layer 6 by thermal oxidation of the semiconductor substrate 1 and the second semiconductor layer 6. To form the buried insulating layer 11 by thermal oxidation of the semiconductor substrate 1 and the second semiconductor layer 6, it is preferable that low-temperature wet oxidation that provides reaction rate controlling be used to improve embedding properties. Here, after the buried insulating layer 11 is formed in the cavity 10, high-temperature annealing may be performed at 1100 degrees centigrade or more. It is therefore possible to reflow the buried insulating layer 11 to reduce stress on the buried insulating layer 11, and also to reduce the interface state at the boundary with the second semiconductor layer 6. Further, the buried insulating layer 11 may be formed to entirely fill the cavity 10 or leave part of the cavity 10 unfilled.

While the method referring to FIG. 11B provides the buried insulating layer 11 in the cavity 10 between the semiconductor substrate 1 and the second semiconductor layer 6 by thermal oxidation of the semiconductor substrate 1 and the second semiconductor layer 6, the buried insulating layer 11 can also be embedded in the cavity 10 by providing an insulating film therein by CVD.

Accordingly, it is possible to fill the cavity 10 between the substrate 1 and the second semiconductor layer 6 with other materials than an oxide film, while preventing reduction in the thickness of the second semiconductor layer 6. It is therefore possible to increase the thickness of the buried insulating layer 11 arranged in the back surface of the second semiconductor layer 6 and reduce a dielectric constant, thereby reducing the parasitic capacitance of the back surface of the second semiconductor layer 6.

Examples of the material of the buried insulating layers 11 include fluorosilicate glass (FSG) and a silicon nitride film as well as a silicon oxide film. Further, the buried insulating layer 11 may be made of phosphorous-doped glass (PSG), boron-phosphorous-doped glass (BPSG), polyarylene ether (PAE), hydrogen silsesquioxane (HSQ), methyl silsesquioxane (MSQ), polychlorinated biphenyl (PCB), carbon fluoride (CF), SiOC, SiOF, and other organic low-k films, and their porous films as well as a spin-on glass (SOG) film.

Next, as shown in FIGS. 12A through 12C, after the buried insulating layer 11 is formed in the cavity 10 between the semiconductor substrate 1 and the second semiconductor layer 6, a buried insulating member 12 is deposited over the whole surface by CVD or the like. As the buried insulating member 12, a silicon oxide film may be used, for example. After the buried insulating member 12 and the support member 8 are made thin by CMP or the like, the anti-oxidation film 7a is etched by wet etching using thermal phosphoric acid so as to form the STI structure in which the surfaces of the pad oxide film 4 and the underlying oxide film 7 are exposed, the trench 3a is embedded with the support member 8, and the inside of the trench 9 is filled with the buried insulating member 12.

Then, by removing the pad oxide film 4 and the underlying oxide film 7, the surface of the second semiconductor layer 6 is exposed as well as the surface of the semiconductor substrate 1 in the bulk region R2 is exposed. Subsequently, thermal oxidation is performed to the surfaces of the second semiconductor layer 6 and the semiconductor substrate 1 so as to form the gate insulating films 20a and 20b respectively on the surfaces thereof Then, a polycrystalline silicon layer is formed by CVD, for example, on the second semiconductor layer 6 and the semiconductor substrate 1 provided with the gate insulating films 20a and 20b. Then the polycrystalline silicon layer is patterned by photolithography and etching to form the gate electrodes 21a and 21b. The gate electrode 21a is formed on the second semiconductor layer 6 so that the end part thereof reaches the STI structure, while the gate electrode 21b is formed on the semiconductor substrate 1 so that the end part thereof reaches the LOCOS structure 3. By forming the gate electrode 21a on the second semiconductor layer 6 so that the end part thereof reaches the STI structure, the gate electrode 21a can be arranged avoiding the border between the LOCOS structure 3 and the STI structure. Accordingly, a leak current from the gate electrode 21a to the semiconductor substrate 1, and deterioration of reliability of the gate insulating film 20a are prevented.

Next, by ion-implanting one of impurities such as As, P, and B to the second semiconductor layer 6 and the semiconductor substrate 1 using the gate electrodes 21a and 21b as masks, a CVD layer made of low concentration impurity implantation layers arranged on the both sides of each of the gate electrodes 21a and 21b are formed on the second semiconductor layer 6. After an insulating layer is formed on the second semiconductor layer 6 provided with the LDD layer by CVD or the like, the side walls 22a and 22b are formed respectively on the side walls of the gate electrodes 21a and 21b by etching back the insulating layer by anisotropic etching such as RIE. Then, one of impurities such as As, P, and B is ion-implanted to the second semiconductor layer 6 and the semiconductor substrate 1 using the gate electrodes 21a and 21b, and the side walls 22a and 22b as masks. Thus, source/drain layers 23a and 23b, which are high concentration impurity implanted layers and arranged on each of both sides of the side walls 22a and 22b respectively, are formed thereby on the second semiconductor layer 6 and the semiconductor substrate 1.

Consequently, the method can provide the SOI structure in a part of the region isolated by the STI structure on the semiconductor substrate 1 as well as the bulk structure in other part of the region isolated by the LOCOS structure 3 on the semiconductor substrate 1 while reducing defect occurrences of the second semiconductor layer 6. Thereby, it becomes possible to form the SOI structure and the bulk structure on the same semiconductor substrate 1 without using an SOI substrate, while an isolation breakdown voltage is improved and a leak current from the gate electrode 21a to a semiconductor substrate 1, and deterioration of reliability of the gate insulating film 20a. are prevented. As a result, it becomes possible to mount both an SOI transistor and a high-breakdown-voltage transistor on the same semiconductor substrate 1 and improve reliability of the SOI transistor and the high-breakdown-voltage transistor while manufacturing cost is prevented from increasing.

For example, a logic circuit with a fully depleted SOI transistor is formed in the SOI forming region R1 while a middle-breakdown-voltage analog circuit with a bulk transistor is formed in the bulk region R2.

What is claimed is:

1. A semiconductor device, comprising:
a semiconductor substrate;
a well formed on the semiconductor substrate;
a semiconductor layer formed by epitaxial growth avoiding the well;
a buried insulating layer embedded between the semiconductor substrate and the semiconductor layer;
a first gate electrode formed on the semiconductor layer, the first gate electrode having a first side and a second side;
a first source layer and a first drain layer formed on the semiconductor layer, the first source layer being arranged on the first side of the first gate electrode and the first drain layer being arranged on the second side of the first gate electrode;
a second gate electrode formed on the well, the second gate electrode having a third side and a fourth side; and
a second source layer and a second drain layer formed on the well, the second source layer being arranged on the third side of the second gate electrode and the second drain layer being arranged on the fourth side of the second gate electrode.

2. The semiconductor device according to claim 1,
the well having a P well and a N well,
the second gate electrode formed on the P well, the second gate electrode having a third side and a fourth side;
an N-type source layer and an N-type drain layer formed on the P well, the N-type source layer being arranged on the third side of the second gate electrode and the N-type drain layer being arranged on the fourth side of the second gate electrode;
a third gate electrode formed on the N well, the third gate electrode having a fifth side and a sixth side; and
a P-type source layer and a P-type drain layer formed on the N well, the P-type source layer being arranged on the fifth side of the third gate electrode and the P-type drain layer being arranged on the sixth side of the third gate electrode.

3. A method for manufacturing a semiconductor device, comprising:
forming a well on a semiconductor substrate;
forming a first semiconductor layer on the semiconductor substrate avoiding the well;
forming a second semiconductor layer having a smaller etching rate than an etching rate of the first semiconductor layer on the first semiconductor layer;
forming a support member supporting the second semiconductor layer on the semiconductor substrate;
forming an exposing part to expose at least a part of the first semiconductor layer from the second semiconductor layer;
selectively etching the first semiconductor layer through the exposing part to form a cavity under the second semiconductor layer by removing the first semiconductor layer;
forming a buried insulating layer embedded in the cavity through the exposing part;
forming a first gate electrode on the second semiconductor layer through a first gate insulating film, the first gate electrode having a first side and a second side;
forming a first source layer and a first drain layer on the second semiconductor layer, the first source layer being arranged on the first side of the first gate electrode and the first drain layer being arranged on the second side of the first gate electrode;
forming a second gate electrode on the well through a second gate insulating film, the second gate electrode having a third side and a fourth side; and
forming a second source layer and a second drain layer on the well, the second source layer being arranged on the third side of the second gate electrode and a second drain layer being arranged on the fourth side of the second gate electrode.

4. The method for manufacturing a semiconductor device according to claim 3,
the well having a P well and a N well,
the second gate electrode formed on the P well, the second gate electrode having a third side and a fourth side;
forming of the support member including:
forming a first trench on the semiconductor substrate through the second semiconductor layer and the first semiconductor layer to expose a part of the semiconductor substrate and embedded in the first trench on the semiconductor substrate to cover the second semiconductor layer,
in the forming of the second gate electrode, the second gate electrode formed on the P well through a second gate insulating film and having a third side and a fourth side; and further comprising:
forming an N-type source layer and an N-type drain layer on the P well, the N-type source layer being arranged on the third side of the second gate electrode and the N-type drain layer being arranged on the fourth side of the second gate electrode;
forming a third gate electrode on the N well through a third gate insulating film, the third gate electrode having a fifth side and a sixth side; and
forming a P-type source layer and a P-type drain layer on the N well, the P-type source layer being arranged on the fifth side of the third gate electrode and the P-type drain layer being arranged on the sixth side of the third gate electrode

5. A semiconductor device, comprising:
a semiconductor substrate;
a well formed on the semiconductor substrate;
a semiconductor layer formed on the well by epitaxial growth;
a buried insulating layer embedded between the semiconductor substrate and the semiconductor layer;
a first field-effect transistor formed on the semiconductor layer;
a second field-effect transistor formed on the well, including a channel having a same conductivity type as a conductivity type of the first field-effect transistor.

6. The semiconductor device according to claim 5,
the well having a P well and a N well;
the first field-effect transistor having a first N-channel field-effect transistor formed on the semiconductor layer on the P well and a first P-channel field-effect transistor formed on the semiconductor layer on the N well;
the second field-effect transistor having a second N-channel field-effect transistor formed on the P well and a second P-channel field-effect transistor formed on the N well.

7. A method for manufacturing a semiconductor device, comprising:
forming a well on a semiconductor substrate;
forming a first semiconductor layer on the well;
forming a second semiconductor layer having a smaller etching rate than an etching rate of the first semiconductor layer on the first semiconductor layer;
forming a support member supporting the second semiconductor layer on the semiconductor substrate;
forming an exposing part to expose at least a part of the first semiconductor layer from the second semiconductor layer;
selectively etching the first semiconductor layer through the exposing part to form a cavity under the second semiconductor layer by removing the first semiconductor layer;
forming a buried insulating layer embedded in the cavity through the exposing part;
forming a first field-effect transistor on the semiconductor layer;
forming a second field-effect transistor on the well, including a channel having a same conductivity type as a conductivity type of the first field-effect transistor.

8. The method for manufacturing a semiconductor device according to claim 7,
the well having a P well and a N well;
the first field-effect transistor having a first N-channel field-effect transistor formed on the semiconductor layer on the P well and a first P-channel field-effect transistor formed on the semiconductor layer on the N well;
the second field-effect transistor having a second N-channel field-effect transistor formed on the P well and a second P-channel field-effect transistor formed on the N well.

9. A semiconductor device, comprising:
a semiconductor substrate isolated by a local oxidation of silicon (LOCOS) structure;
a semiconductor layer formed inside of an active region defined by the local oxidation of silicon (LOCOS) structure by epitaxial growth through a buried insulating layer;
a shallow trench isolation (STI) structure arranged between the semiconductor layer and the local oxidation of silicon (LOCOS) structure;
a gate electrode formed on the semiconductor layer so that an end part of the gate electrode reaches the shallow trench isolation (STI) structure, the gate electrode having a first side and a second side; and
a source layer and a drain layer formed on the semiconductor layer, the source layer being arranged on the first side of the gate electrode and a drain layer being arranged on the second side of the gate electrode.

10. The semiconductor device according to claim 9, further comprising:
a second source layer and a second drain layer formed on the semiconductor substrate, the second source layer being arranged on the third side of the second gate electrode and the second drain layer being arranged on the fourth side of the second gate electrode.

11. A method for manufacturing a semiconductor device, comprising:
forming a local oxidation of silicon (LOCOS) structure to isolate a semiconductor substrate;
a first semiconductor layer on the semiconductor substrate isolated by the local oxidation of silicon (LOCOS) structure;
forming a second semiconductor layer having a smaller etching rate than an etching rate of the first semiconductor layer on the first semiconductor layer;
forming a first trench on the semiconductor substrate through the second semiconductor layer and the first semiconductor layer to expose a part of the semiconductor substrate;
forming a support member embedded in the first trench on the semiconductor substrate to cover the second semiconductor layer;
forming a second trench on the semiconductor substrate through the second semiconductor layer and the first semiconductor layer to expose a part of an end part of the first semiconductor layer;
selectively etching the first semiconductor layer through the second trench to form a cavity under the second semiconductor layer by removing the first semiconductor layer;
forming a buried insulating layer embedded in the cavity;
forming a shallow trench isolation (STI) structure having the first trench filled with the support member by making the support member thin;
forming a gate electrode on the second semiconductor layer so that an end part of the gate electrode reaches the shallow trench isolation (STI) structure, the gate electrode having a first side and a second side; and
forming a source layer and a drain layer on the second semiconductor layer, the source layer being arranged on the first side of the gate electrode and the drain layer being arranged on the second side of the gate electrode.

12. The method for manufacturing a semiconductor device according to claim 11, further comprising:
forming a second gate electrode in a second region on the semiconductor substrate isolated by the local oxidation of silicon (LOCOS) structure, the second gate electrode having a third side and a fourth side; and
forming a second source layer and a second drain layer formed on the semiconductor substrate, the second source layer being arranged on the third side of the second gate electrode and the second drain layer being arranged on the fourth side of the second gate electrode.
